(19) United States
(12) Patent Application Publication
(10) Pub. No.: US 2017/0077457 A1
(43) Pub. Date: Mar. 16, 2017

(54) MIRROR DISPLAY APPARATUS AND METHOD OF MANUFACTURING THE SAME

(71) Applicant: Samsung Display Co., LTD., Yongin-si (KR)

(72) Inventors: Su-Hwan LEE, Asan-si (KR); Eun-Ho KIM, Cheonan-si (KR); Jin-Woo PARK, Asan-si (KR)

(21) Appl. No.: 15/214,560

(22) Filed: Jul. 20, 2016

(30) Foreign Application Priority Data
Sep. 15, 2015 (KR) 10-2015-0130072

(51) Int. Cl. H01L 51/52; H01L 27/32; H01L 51/56; H01L 51/00

(52) U.S. Cl. CPC H01L 51/5271; H01L 51/0097; H01L 27/3211; H01L 51/56; H01L 27/3276; H01L 27/3246; H01L 2227/323; H01L 51/0081; H01L 2251/558

(57) ABSTRACT

A mirror display apparatus includes: a display unit disposed on a first substrate of a display substrate; and a mirror substrate facing the display substrate. The mirror substrate includes: a mirror pattern provided in plural on a second substrate facing the first substrate with respect to the display unit; an organic layer facing the first substrate with respect to the display unit; and a mirror layer extending continuously between the mirror patterns and the organic layer.

This application claims priority to Korean Patent Application No. 10-2015-0130072 filed on Sep. 15, 2015, and all the benefits accruing therefrom under 35 U.S.C. §119, the content of which in its entirety is herein incorporated by reference.

### BACKGROUND

1. Field

Exemplary embodiments relate to a mirror display apparatus. More particularly, exemplary embodiments relate to a mirror display apparatus including a plurality of mirror patterns and a method of manufacturing the same.

2. Description of the Related Art

A display apparatus, e.g., an organic light emitting display (“OLED”) device or a liquid crystal display (“LCD”) device having a mirror property together with an image display property has been researched.

Layer structures or patterns having a reflective property may be inserted to the display device so as to realize the mirror property. However, a manufacturing process or a display quality of the display apparatus may be affected adversely due to an implementation of the mirror property.

### SUMMARY

Exemplary embodiments provide a mirror display apparatus having an improved display quality.

Exemplary embodiments provide a method of manufacturing a mirror display apparatus having an improved display quality.

According to exemplary embodiments, there is provided a mirror display apparatus. The mirror display apparatus includes a display unit disposed on a first substrate of a display substrate; and a mirror substrate facing the display substrate. The mirror substrate includes a mirror pattern provided in plural on a second substrate facing the first substrate with respect to the display unit; an organic layer facing the first substrate with respect to the display unit; and a mirror layer extending continuously between the mirror patterns and the organic layer.

In exemplary embodiments, the organic layer may include Alq3 (8-hydroxyquinoline aluminum).

In exemplary embodiments, the organic layer facing the first substrate with respect to the display unit may extend continuously between the mirror layer and the display unit.

In exemplary embodiments, the organic layer facing the first substrate with respect to the display unit may extend discontinuously between the mirror layer and the display unit to be disposed between adjacent mirror patterns.

In exemplary embodiments, the display unit may include an emitting region at which light is emitted and a non-emitting region at which light is not emitted. The emitting region of the display unit may be defined overlapping a stacked structure including the mirror layer and the organic layer of the mirror substrate. The non-emitting region of the display unit may be defined overlapping a stacked structure including the mirror layer and each of the mirror patterns of the mirror substrate.

In exemplary embodiments, the emitting region may define first and second color regions of the display unit. The organic layer may define a first portion thereof having a first thickness overlapping the first color region of the display unit and a second portion thereof having a second thickness overlapping the second color region of the display unit, and the first and second thicknesses may be substantially the same as each other.

In exemplary embodiments, the emitting region may define first and second color regions of the display unit. The organic layer may define a first portion thereof having a first thickness overlapping the first color region of the display unit and a second portion thereof having a second thickness overlapping the second color region of the display unit, and the first and second thicknesses may be different from each other.

In exemplary embodiments, the emitting region may define first to third color regions of the display unit. The organic layer may define first to third portions thereof having a respective one of first to third thicknesses which may overlap a respective one of the first to third color regions. The first to third thicknesses may be substantially the same as one another.

In exemplary embodiments, each of the first to third color regions may be a respective one of a red color region, a green color region and a blue color region.

In exemplary embodiments, the emitting region may define first to third color regions of the display unit. The organic layer may define first to third portions thereof having a respective one of first to third thicknesses which may overlap a respective one of the first to third color regions. The first to third thicknesses may be different from one another.

In exemplary embodiments, each of the first to third color regions may be a respective one of a red color region, a green color region and a blue color region. The first thickness may be greater than the second and third thicknesses. The third thickness may be less than the first and second thicknesses.

In exemplary embodiments, the mirror patterns may include a metal.

In exemplary embodiments, the display unit may include an organic light emitting layer.

According to exemplary embodiments, there is provided a mirror display apparatus. The mirror display apparatus includes a display unit disposed on a first substrate of a display substrate; and a mirror substrate facing the display substrate. The display unit includes an emitting region including first and second color regions. The mirror substrate includes a mirror pattern provided in plural on a second substrate facing the first substrate with respect to the display unit; and an organic layer facing the first substrate with respect to the display unit. The organic layer includes first and second portions overlapping the first and second color regions, respectively. A first thickness of the first portion of the organic layer is different from a second thickness of the second portion of the organic layer.

In exemplary embodiments, the organic layer may include Alq3 (8-hydroxyquinoline aluminum).

In exemplary embodiments, the display unit may further include a non-emitting region at which light is not emitted. The non-emitting region of the display unit may be defined to overlap a structure including each of the mirror patterns of the mirror substrate.

In exemplary embodiments, each of the first and second color regions may be a respective one of a red color region and a green color region, and the first thickness may be greater than the second thickness.

In exemplary embodiments, the emitting region may further include a third color region. The organic layer may further include a third portion overlapping the third color region, and a third thickness of the third portion of the organic layer may be different from the first and second thicknesses.

In exemplary embodiments, each of the first to third color regions may be a respective one of a red color region, a green color region and a blue color region. The first thickness may be greater than the second and third thicknesses, and the third thickness is less than the first and second thicknesses.

In exemplary embodiments, the mirror display apparatus may further include a mirror layer between the mirror patterns and the organic layer.

In one or more exemplary embodiment of a mirror display apparatus in accordance with the invention, an organic layer is disposed under a plurality of mirror patterns and a mirror layer to be closest to the display unit of a display substrate such that color characteristics of color light to be displayed in the mirror display apparatus is calibrated.

In particular, thicknesses of portions of the organic layer may be adjusted so that characteristics of red, green and blue colors are calibrated and a display quality of the mirror display apparatus is enhanced.

### BRIEF DESCRIPTION OF THE DRAWINGS

Exemplary embodiments will be more clearly understood from the following detailed description taken in conjunction with the accompanying drawings.

FIG. 1 is a cross-sectional view illustrating an exemplary embodiment of a mirror display apparatus in accordance with the invention.

FIG. 2 is an enlarged view of region A of FIG. 1.

FIGS. 3 to 8 are cross-sectional views illustrating an exemplary embodiment of a method of manufacturing a mirror display apparatus in accordance with the invention.

FIG. 9 is a cross-sectional view illustrating another exemplary embodiment of a mirror display apparatus in accordance with the invention.

FIG. 10 is an enlarged view of region C of FIG. 9.

FIG. 11 is a cross-sectional view illustrating still another exemplary embodiment of a mirror display apparatus in accordance with the invention.

FIG. 12 is an enlarged view of region D of FIG. 11.

### DETAILED DESCRIPTION

Various exemplary embodiments will be described more fully hereinafter with reference to the accompanying drawings, in which some exemplary embodiments are shown. The invention may, however, be embodied in many different forms and should not be construed as limited to the exemplary embodiments set forth herein. Rather, these exemplary embodiments are provided so that this disclosure will be thorough and complete, and will fully convey the scope of the invention to those skilled in the art. In the drawings, the sizes and relative sizes of layers and regions may be exaggerated for clarity. Like numerals refer to like elements throughout.

It will be understood that when an element is referred to as being “on” another element, it can be directly on the other element or intervening elements may be present therebetween. In contrast, when an element is referred to as being “directly on” another element, there are no intervening elements present.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments only and is not intended to be limiting. As used herein, the singular forms “a,” “an,” and “the” are intended to include the plural forms, including “at least one,” unless the content clearly indicates otherwise. “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The exemplary term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The exemplary terms “below” or “beneath” can, therefore, encompass both an orientation of above and below.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Exemplary embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

In a display apparatus, a structure for implementation of both a reflective (e.g., mirror) property, and a display property for which light is calibrated to display a desired color, is employed.

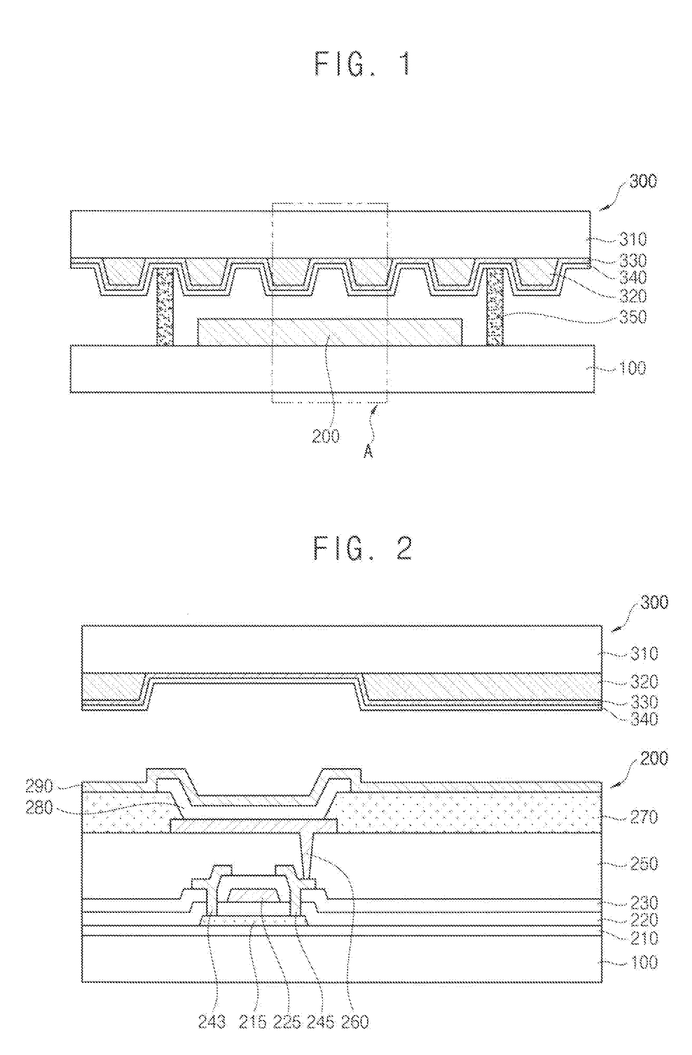

FIG. 1 is a cross-sectional view illustrating an exemplary embodiment of a mirror display apparatus in accordance with the invention. FIG. 2 is an enlarged view of region A of FIG. 1.

Referring to FIGS. 1 and 2, a mirror display apparatus includes a display substrate including a display unit 200 disposed on a first substrate 100, and a mirror substrate 300 facing the first substrate 100 with respect to the display unit 200. A pixel is defined in plural in the display unit 200. The display unit 200 may include an emitting region at which light is emitted or an image is displayed, and a pixel region (e.g., a non-emitting region) at which light is not emitted or an image is not displayed. The first substrate 100 may serve as a base substrate of the display substrate.

The mirror substrate 300 may include a mirror pattern 320 provided in plural on under a second substrate 310, a mirror layer 330 extending continuously and commonly under surfaces of the mirror patterns 320 and the second substrate 310, and an organic layer 340 stacked under the mirror layer 330.

The first substrate 100 may include, e.g., a glass substrate, a transparent plastic substrate or a flexible plastic substrate. The first substrate 100 may support the display unit 200 described later.

The display unit 200 may include a switching device on the first substrate 100 and a display structure electrically connected to the switching device.

The switching device may include, e.g., a thin film transistor (“TFT”) including an active pattern 215, a gate insulation layer 220, a gate electrode 225, a source electrode 243 and a drain electrode 245. The display structure may include, e.g., a first electrode 260, a display layer 280 and the second electrode 290.

A barrier layer 210 may be disposed or formed on an upper surface of the first substrate 100. Moistures penetrating through the first substrate 100 may be blocked by the barrier layer 210, and impurity diffusion between the display unit 200 and structures therein may be also blocked by the barrier layer 210.

In an exemplary embodiment, for example, the barrier layer 210 may include silicon oxide, silicon nitride or silicon oxynitride. These materials may be used alone or in a combination thereof. In an exemplary embodiment, the barrier layer 210 may have a multi-layered structure including a silicon oxide layer and a silicon nitride layer.

The active pattern 215 may include a silicon compound such as polysilicon. In some exemplary embodiments, the active pattern 215 may include an oxide semiconductor such as indium gallium zinc oxide (“IGZO”), zinc tin oxide (“ZTO”) or indium tin zinc oxide (“ITZO”). In an exemplary embodiment of manufacturing the display apparatus, for example, an active layer including the silicon compound or the oxide semiconductor may be formed by a sputtering process, and then may be patterned by a photo-lithography process.

The gate insulation layer 220 may be disposed or formed on the barrier layer 210, and cover the active pattern 215. The gate insulation layer 220 may include silicon oxide, silicon nitride and/or silicon oxynitride. The gate insulation layer 220 may have a multi-layered structure including a silicon oxide layer and a silicon nitride layer.

The gate electrode 225 may be disposed or formed on the gate insulation layer 220, and may be superimposed over the active pattern 215. In an exemplary embodiment of manufacturing the display apparatus, for example, a first conductive layer may be formed on the gate insulation layer 220, and may be patterned by a photo-lithography process to form the gate electrode 225. The first conductive layer may include or be formed of a metal such as Al, Ag, W, Cu, Mo, Ti, Ta, Cr, etc., or a nitride thereof by a sputtering process or an atomic layer deposition (“ALD”) process. The first conductive layer may be disposed or formed as a multi-layered structure such as an Al/Mo structure or a Ti/Cu structure.

In some exemplary embodiments of manufacturing the display apparatus, a scan line may be also formed from the first conductive layer from which the gate electrode 225 is formed. The gate electrode 225 may be diverged from the scan line.

In some exemplary embodiments of manufacturing the display apparatus, an ion-implantation process may be performed using the gate electrode 225 as an implantation mask such that a source region and a drain region of the active pattern 215 may be formed at both of opposing ends of the active pattern 215. A portion of the active pattern 215 between the source and drain regions thereof, which may overlap the gate electrode 225, may be defined as a channel region through which a charge may be mover or transferred.

An insulating interlayer 230 may be disposed or formed on the gate insulation layer 220, and may cover the gate electrode 225. The insulating interlayer 230 may include silicon oxide, silicon nitride and/or silicon oxynitride. The insulating interlayer 230 may have a multi-layered structure including a silicon oxide layer and a silicon nitride layer.

The source electrode 243 and the drain electrode 245 may extend through the insulating interlayer 230 and the gate insulation layer 220 to be in contact with the active pattern 215. The source electrode 243 and the drain electrode 245 may be in contact with the source region and the drain region, respectively, of the active pattern 215, such as at a contact hole in layers therebetween.

In an exemplary embodiment of manufacturing the display apparatus, for example, the insulating interlayer 230 and the gate insulation layer 220 may be partially etched to form contact holes through which the active pattern 215 may be exposed. A second conductive layer filling the contact holes may be formed on the insulating interlayer 230, and may be patterned by a photo-lithography process to form the source electrode 243 and the drain electrode 245. The second conductive layer may include or be formed from a material and a process substantially the same as or similar to those for the first conductive layer.

In some exemplary embodiments of manufacturing the display apparatus, a data line may be also formed from the second conductive layer from which the source electrode 243 and the drain electrode 245 are formed. The source electrode 243 may be diverged from the data line.

The TFT may be disposed or formed in each pixel of the display unit 200 by the processes as described above. In some exemplary embodiments, at least two TFTs and a capacitor may be disposed or formed in each pixel.

A via insulation layer 250 may be disposed or formed on the insulating interlayer 230, and may cover the source and drain electrodes 243 and 245. The via insulation layer 250 may include or be formed using an organic material such as polyimide, an epoxy resin, an acrylate-based resin, or polyester by a spin coating process or a slit coating process. The via insulation layer 250 may also serve as a planarization layer of the display unit 200.

The display structure may be formed on the via insulation layer 250.

The first electrode 260 may extend through the via insulation layer 250, and may be electrically connected to the drain electrode 245 such as at a contact hole in a layer therebetween. In an exemplary embodiment of manufacturing the display apparatus, for example, the via insulation layer 250 may be partially etched to form a via hole through which the drain electrode 245 may be exposed. A third conductive layer sufficiently filling the via hole may be formed on the via insulation layer, and may be patterned by a photo-lithography process to form the first electrode 260.

The first electrode 260 may serve as an anode or a pixel electrode of the display structure, and may be disposed or formed in each pixel included in the display unit 200.

In an exemplary embodiment of manufacturing the display apparatus, the third conductive layer may include or be formed from a material and a process substantially the same as or similar to those for the first conductive layer. In some exemplary embodiments, the third conductive layer may include or be formed of a transparent conductive layer such as indium tin oxide (“ITO”), indium zinc oxide (“IZO”), zinc oxide, indium oxide, etc.

A pixel defining layer (“PDL”) 270 may be disposed or formed on the via insulation layer 250 to cover a peripheral portion of the first electrode 260. In an exemplary embodiment of manufacturing the display apparatus, for example, the PDL 270 may be formed using a photosensitive organic material by exposure and developing processes. Alternatively, the PDL 270 may be formed of a silicon-based inorganic material by a photo-lithography process.

In exemplary embodiments, an area of the first electrode 260 exposed by the PDL 270 may substantially correspond to an emitting region of the each pixel in the display unit 200.

The display layer 280 may be disposed or formed on the first electrode 260 and the PDL 270. In exemplary embodiments, the display layer 280 may include an organic light emitting material for generating light, and the display device may be provided as an organic light emitting display (“OLED”) device. For the OLED, a hole transport layer (“HTL”) and an electron transport layer (“ETL”) may be further disposed or formed under the display layer 280 and on the display layer 280, respectively.

In an exemplary embodiment of manufacturing the display apparatus, the display layer 280 may be formed by individually printing the organic light emitting material at the each pixel. The HTL and the ETL may be formed at the each pixel, or may be formed commonly at a plurality of the pixels.

In some exemplary embodiments, a liquid crystal material may be used for the display layer 280. Where the liquid crystal material may be used for the display layer 280, the display device may be provided as an LCD device.

The second electrode 290 may be disposed or formed on the PDL 270 and the display layer 280. In some exemplary embodiments, the second electrode 290 may serve as a common electrode common to the plurality of the pixels. The second electrode 290 may also serve as a cathode of the display unit 200.

In an exemplary embodiment of manufacturing the display apparatus, the second electrode 290 may be formed by a depositing a metal or a transparent conductive material as mentioned above through, e.g., an open mask. In an exemplary embodiment, for example, within the display substrate, the TFT may drive the first and second electrodes 260 and 290 such that the display unit 200 of the display substrate generates light using the display layer 280. The light generated by the display unit 200 is provided to the mirror substrate 300.

As described above, the mirror substrate 300 may include the second substrate 310, the mirror patterns 320, the mirror layer 330 and the organic layer 340.

The second substrate 310 may include, e.g., a glass substrate, a transparent plastic substrate or a flexible plastic substrate, and may serve as a base substrate of the mirror substrate 300. The second substrate 310 may support the mirror patterns 320, the mirror layer 330 and the organic layer 340 of the mirror substrate 300 thereon.

Referring to FIGS. 1 and 2, the mirror patterns 320 may be arranged under the second substrate 310. In an exemplary embodiment, for example, the mirror patterns 320 may be arranged in, e.g., a grid shape, a line shape, a mesh shape or a plurality of islands shape. Such shapes may be defined in a top plan view of the display apparatus.

The mirror pattern 320 may include a material having a relatively high reflectivity. In exemplary embodiments, the mirror pattern 320 may include a metal such as aluminum (Al), chromium (Cr), copper (Cu), silver (Ag), titanium (Ti), tantalum (Ta), molybdenum (Mo), tungsten (W), etc. The mirror pattern 320 may have a single metal layered structure. In some exemplary embodiments, the mirror pattern 320 may have, e.g., a double-layered structure or a triple-layered structure which includes a plurality of different metal layers.

When the mirror substrate 300 serves as the encapsulation substrate of the display apparatus, the mirror pattern 320 may overlap a region except for an emitting region among the pixel region (e.g., a non-emitting region) in the display unit 200. Where the mirror pattern 320 does not overlap the emitting region, an area between the neighboring mirror patterns 320 of the mirror substrate 300 may overlap the emitting region of the pixel region in the display unit 200.

The mirror layer 330 may be disposed or formed under the second substrate 310 to cover surfaces of the mirror patterns 320. In exemplary embodiments, the mirror layer 330 may extend commonly and continuously under the second substrate 310.

The mirror layer 330 may have, e.g., a double-layered structure or a triple-layered structure which includes a plurality of different metal layers. Alternatively, the mirror layer 330 may have a single metal layered structure.

In an exemplary embodiment, for example, the mirror layer 330 may include a metal such as aluminum (Al), chromium (Cr), copper (Cu), silver (Ag), titanium (Ti), tantalum (Ta), molybdenum (Mo), tungsten (W), etc.

In exemplary embodiments, a portion of the mirror layer 330 between neighboring the mirror patterns 320 may overlap the emitting region of the display unit 200.

The mirror layer 330 may be in contact with a bottom surface of the second substrate 310 exposed by the mirror patterns 320 and with lower surfaces of the minor patterns 320. For example, the mirror layer 330 may be a transflective layer.

The organic layer 340 may be stacked under the minor layer 330. The organic layer 340 may extend continuously along a lower surface of the mirror layer 330.

The organic layer 340 may include 8-hydroxyquinoline aluminum. Accordingly, the organic layer 340 may have a predetermined refractive index such that characteristic of a light which is provided from the display substrate and which is transmitted through the organic layer 340 of the minor substrate 300 is calibrated, such as to have a specific color, wavelength, intensity, etc. to be emitted by the mirror substrate 300.

In exemplary embodiments, the organic layer 340 may have a uniform thickness. The thickness may be taken in a direction normal to the lower surfaces of the mirror layer 330.

The display unit 200 may include the emitting region and the non-emitting region. The emitting region of the display substrate may overlap a stacked structure including the mirror layer 330 and the organic layer 340 of the mirror substrate 300, and the non-emitting region of the display substrate may overlap a stacked structure including the mirror layer 330 and each of the mirror patterns 320.

In an exemplary embodiment, for example, the emitting region of the display unit 200 may include or define first to third color regions. Each of the first to third color regions may be a respective one of a red region, a green region and a blue region, but are not limited thereto.

The organic layer 340 of the minor substrate 300 may calibrate a red light emitted through the red color region, a blue light emitted through the blue color region and a green light emitted through the green color region.

A sealing member 350 may be interposed between the first substrate 100 and the second substrate 310 such that the display unit 200 may be encapsulated within the display apparatus. Thus, the mirror substrate 300 may substantially serve as an encapsulation substrate of the display apparatus. The sealing member 350 may be in contact with an organic layer 340 of the mirror substrate 300 and with the first substrate 100 to protect the display unit 200.

In one or more exemplary embodiment of the mirror display apparatus in accordance with the invention, the organic layer 340 is disposed under the mirror patterns 320 and the mirror layer 330 such that a color displayed in the mirror display apparatus is calibrated.

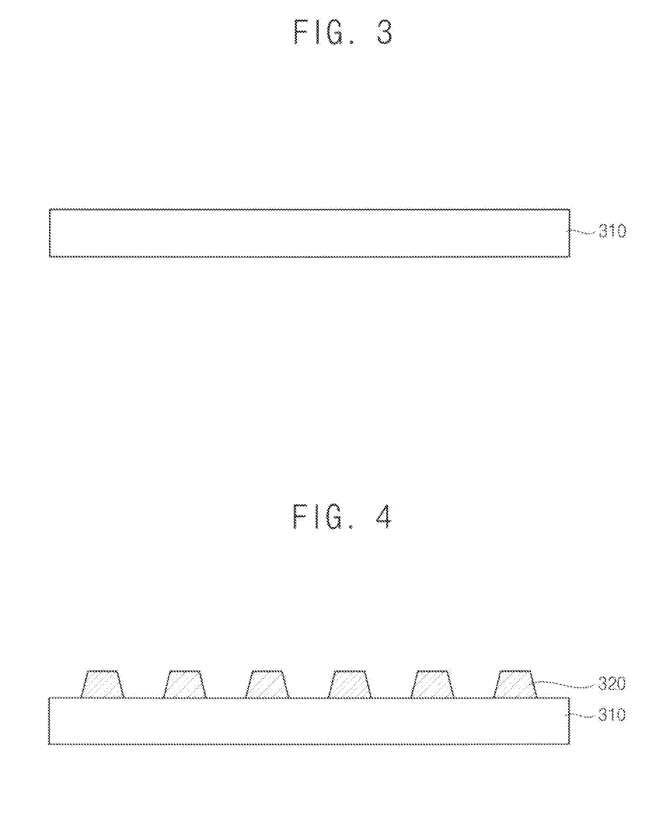

FIGS. 3 to 8 are cross-sectional views illustrating an exemplary embodiment of a method of manufacturing a mirror display apparatus in accordance with the invention. As an exemplary embodiment, for example, FIGS. 3 to 8 illustrate a method of manufacturing the mirror display apparatus of FIG. 1.

Referring to FIGS. 3 and 4, a second substrate 310 may be provided. The second substrate 310 may include a glass substrate, a transparent plastic substrate, a flexible substrate, etc.

A metal layer (not shown) may be formed on the second substrate 310, and the metal layer may be patterned by, e.g., a photo-lithography process to form a mirror pattern 320 in plural on the second substrate 310.

The metal layer may be formed of, e.g., Al, Cr, Cu, Ag, Ti, Ta, Mo, W, or the like. These materials may be used alone or in a combination thereof. The metal layer may be formed by, e.g., a sputtering process, a physical vapor deposition (“PVD”) process, an atomic layer deposition (“ALD”) process, a chemical vapor deposition (“CVD”) process, etc.

In an exemplary embodiment, for example, the mirror patterns 320 may be formed in a grid arrangement, a mesh arrangement or an arrangement including a plurality of islands on the second substrate 310, in a top plan view of the display apparatus.

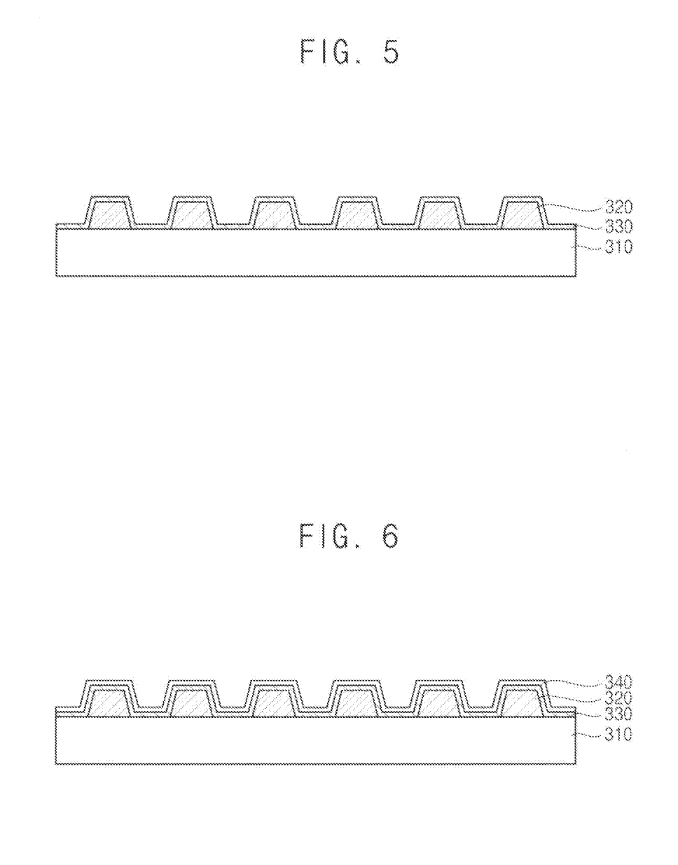

Referring to FIG. 5, a mirror layer 330 may be formed on a lower surface of the second substrate 310 and lower surfaces of the mirror patterns 320. A thickness of the mirror layer 330 may be less than a thickness of the mirror pattern 320, and thus the mirror layer 330 may be a transflective layer. In an exemplary embodiment, a maximum thickness of the mirror layer 330 may be less than a minimum thickness of the mirror patterns 320.

In exemplary embodiments, the mirror layer 330 may commonly cover the mirror patterns 320 and be extended continuously and conformally on the second substrate 310.

The mirror layer 330 may be formed of, e.g., Al, Cr, Cu, Ag, Ti, Ta, Mo, W, or the like. These materials may be used alone or in a combination thereof. The mirror layer 330 may be formed by, e.g., a sputtering process, a physical vapor deposition (“PVD”) process, an atomic layer deposition (“ALD”) process, a chemical vapor deposition (“CVD”) process, etc.

In addition, the mirror layer 330 may have a single metal layered structure. In some exemplary embodiments, the mirror layer 330 may have, e.g., a double-layered structure or a triple-layered structure which includes a plurality of different metal layers.

Referring to FIG. 6, an organic layer 340 may be formed on the mirror layer 330. The organic layer 340 may extend continuously on a surface of the mirror layer 330 so that the organic layer 340 is stacked on the mirror layer 330 and common to the mirror patterns 320.

The organic layer 340 may be stacked on the mirror layer 330 to include Alq3 (8-hydroxyquinoline aluminum). Accordingly, the organic layer 340 may have a predetermined refractive index so that a light transmitted through the organic layer 340 is calibrated.

In an exemplary embodiment, for example, the organic layer 340 may be formed by a CVD process, a plasma enhanced CVD (“PECVD”) process, an ALD process, a thermal evaporation process, a vacuum deposition process, etc.

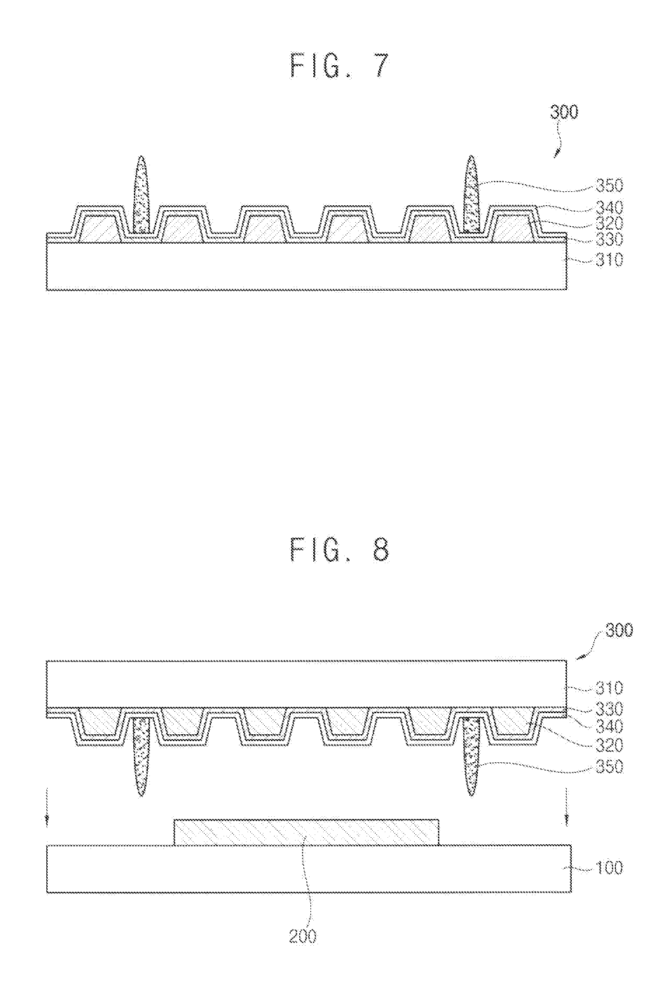

Referring to FIG. 7, a sealing member 350 may be formed on the organic layer 340 such that a mirror substrate 300 is manufactured.

In an exemplary embodiment, for example, the sealing member 350 may be formed using an adhesive resin material such as an epoxy resin or a silicone resin by a printing process or a coating process.

A display substrate may be provided to include a display unit 200 on a first substrate 100.

Referring to FIG. 8, the mirror substrate 300 may be turned over such that the organic layer 340 faces the display substrate. The second substrate 310 of the mirror substrate may be attached to the first substrate 100 on which the display unit 200 is disposed, such that the display unit 200 is encapsulated.

The display unit 200 may include or define an emitting region and a non-emitting region. The emitting region may overlap a stacked structure including the mirror layer 330 and the organic layer 340, and the non-emitting region may overlap a stacked structure including the mirror layer 330 and each of the mirror patterns 320.

For example, the emitting region may include or define first to third color regions. Each of the first to third color regions may be a respective one of a red region, a green region and a blue region of the display unit 200.

The organic layer 340 of the mirror substrate 300 may calibrate a red light emitted through the red color region, a blue light emitted through the blue color region and a green light emitted through the green color region of the display substrate.

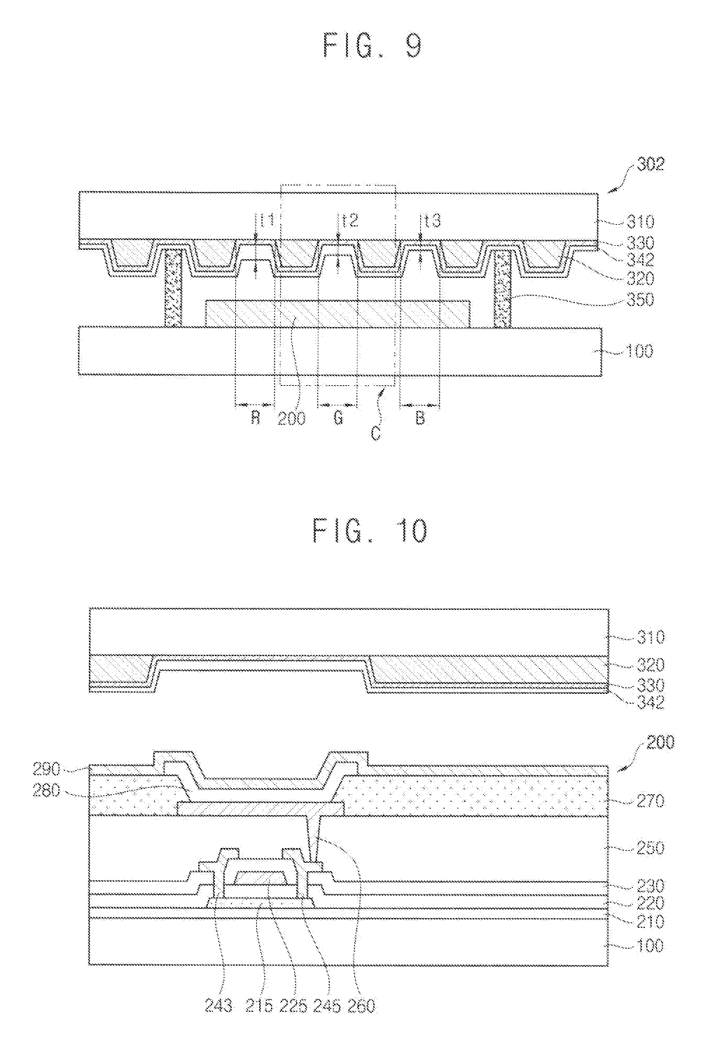

FIG. 9 is a cross-sectional view illustrating another exemplary embodiment of a mirror display apparatus in accordance with the invention. FIG. 10 is an enlarged view of region C of FIG. 9. The mirror display apparatus may be substantially the same as that of FIGS. 1 to 2, except for a thickness of an organic layer. Thus, like reference numerals refer to like elements, and repetitive explanations thereon may be omitted herein.

Referring to FIGS. 9 and 10, a mirror display apparatus includes a display substrate including a display unit 200 disposed on a first substrate 100, and a mirror substrate 302 facing the first substrate 100 with respect to the display unit 200.

The mirror substrate 302 may include a mirror pattern 320 provided in plural under a second substrate 310, a mirror layer 330 extending continuously and commonly on surfaces of the mirror patterns 320 and the second substrate 310, and an organic layer 342 stacked under the mirror layer 330.

The first substrate 100 may include, e.g., a glass substrate, a transparent plastic substrate or a flexible plastic substrate. The first substrate 100 may support the display unit 200 described later.

The display unit 200 may include a switching device on the first substrate 100 and a display structure electrically connected to the switching device.

The mirror substrate 302 may include the second substrate 310, the mirror patterns 320, the mirror layer 330 and the organic layer 342.

The second substrate 310 may include, e.g., a glass substrate, a transparent plastic substrate or a flexible plastic substrate. The second substrate 310 may support the mirror patterns 320, the mirror layer 330 and the organic layer 342.

Referring to FIGS. 9 and 10, the mirror patterns 320 may be arranged under the second substrate 310. In an exemplary embodiment, for example, the mirror patterns 320 may be arranged in, e.g., a grid shape, a line shape, a mesh shape, or a plurality of islands shape.

The mirror layer 330 may be disposed or formed under the second substrate 310 to cover surfaces of the mirror patterns 320. In exemplary embodiments, the mirror layer 330 may extend commonly and continuously under the second substrate 310.

The mirror layer 330 may have, e.g., a double-layered structure or a triple-layered structure which includes a plurality of different metal layers. Alternatively, the mirror layer 330 may have a single metal layered structure. For example, the mirror layer 330 may be a transflective layer.

The organic layer 342 may be stacked under the mirror layer 330. The organic layer 342 may extend continuously along a lower surface of the mirror layer 330.

The organic layer 342 may include 8-hydroxyquinoline aluminum. Accordingly, the organic layer 342 may have a predetermined refractive index such that characteristic of a light transmitted through the organic layer 342 is calibrated.

The display unit 200 may include an emitting region and a non-emitting region. The emitting region of the display substrate may overlap a stacked structure including the mirror layer 330 and the organic layer 342 of the mirror substrate 302, and the non-emitting region of the display substrate may overlap a stacked structure including the mirror layer 330 and each of the mirror patterns 320.

In an exemplary embodiment, for example, the emitting region of the display unit 200 may include or define first to third color regions of the display unit 200. Each of the first to third color regions may be a respective one of a red region R, a green region G, and a blue region B.

Each of first to third portions of the organic layer 342 having a respective one of first to third thicknesses t1, t2 and t3 may overlap a respective one of the first to third color regions. The organic layer 342 at the non-emitting regions of the display substrate extends to define the first to third portions thereof overlapping the first to third color regions of the display substrate. Based on colors of the first to third color regions or wavelengths of lights emitted through (or output from) the first to third color regions, the first to third thicknesses t1, t2 and t3 of the organic layer 342 may be different from one another. Thicknesses of the first to third portions of the organic layer 342 may be taken perpendicular to the second substrate 310 and/or in a direction normal to the lower surface of the overlying mirror layer 330.

In an exemplary embodiment, for example, a thickness of the organic layer 342 overlapping a color region may increase as a wavelength of light output from the color region increases. For example, when the first color region is the red region R, the second color region is the green region G and the third color region is the blue region B, a wavelength of light (e.g., red light) emitted through the first color region may be longer than a wavelength of light (e.g., green light) emitted through the second color region and a wavelength of light (e.g., blue light) emitted through the third color region, and thus the first thickness t1 of the organic layer 342 may be greater than the second and third thicknesses t2 and t3 of the organic layer 342. Similarly, the wavelength of the light emitted through the third color region may be shorter than the wavelength of the light emitted through the first color region and the wavelength of the light emitted through the second color region, and thus the third thickness t3 of the organic layer 342 may be less than the first and second thicknesses t1 and t2.

A sealing member 350 may be disposed between the first and second substrates 110 and 310 such that the display unit 200 is encapsulated within the display apparatus.

In one or more exemplary embodiment, of the mirror display apparatus in accordance with the invention, the organic layer 342 is disposed under the mirror patterns 320 and the mirror layer 330 such that a color displayed in the mirror display apparatus is calibrated.

The first to third thicknesses t1, t2 and t3 of the organic layer 342 of the mirror substrate 302 may be adjusted such that a red light emitted through the red color region, a blue light emitted through the blue color region and a green light emitted through the green color region of the display substrate are calibrated, respectively.

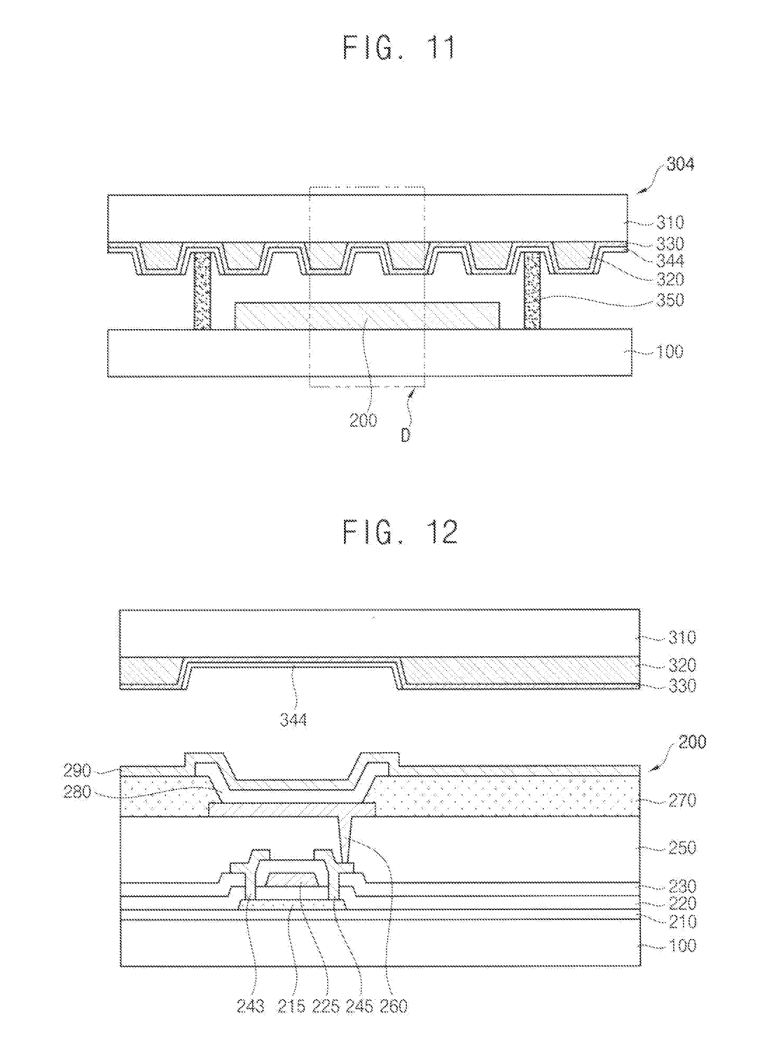

FIG. 11 is a cross-sectional view illustrating still another exemplary embodiment of a mirror display apparatus in accordance with the invention. FIG. 12 is an enlarged view of region D of FIG. 11. The mirror display apparatus may be substantially the same as that of FIGS. 1 to 2, except for an organic layer. Thus, like reference numerals refer to like elements, and repetitive explanations thereon may be omitted herein.

Referring to FIGS. 11 and 12, a mirror display apparatus includes a display substrate including a display unit 200 disposed on a first substrate 100, and a mirror substrate 304 facing the first substrate 100 with respect to the display unit 200.

The mirror substrate 304 may include a mirror pattern 320 provided in plural under a second substrate 310, a mirror layer 330 extending continuously on surfaces of the mirror patterns 320 and the second substrate 310, and an organic layer 344 stacked under the mirror layer 330.

The first substrate 100 may include, e.g., a glass substrate, a transparent plastic substrate or a flexible plastic substrate. The first substrate 100 may support the display unit 200 described later.

The display unit 200 may include a switching device on the first substrate 100 and a display structure electrically connected to the switching device.

The mirror substrate 304 may include the second substrate 310, the mirror patterns 320, the mirror layer 330 and the organic layer 344.

The second substrate 310 may include, e.g., a glass substrate, a transparent plastic substrate or a flexible plastic substrate. The second substrate 310 may support the mirror patterns 320, the mirror layer 330 and the organic layer 344.

Referring to FIGS. 11 and 12, the mirror patterns 320 may be arranged under the second substrate 310. In an exemplary embodiment, for example, the mirror patterns 320 may be arranged in, e.g., a grid shape, a line shape, a mesh shape, or a plurality of islands shape.

The mirror layer 330 may be disposed or formed under the second substrate 310 to cover surfaces of the mirror patterns 320. In exemplary embodiments, the mirror layer 330 may extend commonly and continuously under the second substrate 310.

The mirror layer 330 may have, e.g., a double-layered structure or a triple-layered structure which includes a plurality of different metal layers. Alternatively, the mirror layer 330 may have a single metal layered structure. For example, the mirror layer 330 may be a transflective layer.

The organic layer 344 may be stacked under the mirror layer 330. In exemplary embodiments, the organic layer 344 may be stacked under a portion of the mirror layer 330.

The organic layer 344 may include 8-hydroxyquinoline aluminum. Accordingly, the organic layer 344 may have a predetermined refractive index such that characteristic of a light transmitted through the organic layer 344 is calibrated.

The display unit 200 may include an emitting region and a non-emitting region. The emitting region of the display substrate may overlap a stacked structure including the mirror layer 330 and the organic layer 344 of the mirror substrate 304, and the non-emitting region of the display substrate may overlap a stacked structure including the mirror layer 330 and each of the mirror patterns 320.

In an exemplary embodiment, for example, the organic layer 344 may be stacked under a portion of the mirror layer 330 such that the organic layer 344 overlaps the emitting region of the display unit 200, and the organic layer 344 does not overlap the non-emitting region of the display unit 200. That is, the organic layer 344 defines portions thereof only at the emitting regions of the display unit 200. The portions of the organic layer 344 may terminate at a surface of the mirror layer 330 closest to the display substrate.

A sealing member 350 may be disposed between the first and second substrates 110 and 310 such that the display unit 200 is encapsulated within the display apparatus.

In one or more exemplary embodiment, the mirror display apparatus in accordance with the invention, the organic layer 344 is disposed under the mirror patterns 320 and the mirror layer 330 such that a color displayed at the mirror display apparatus is calibrated.

Accordingly, a red light emitted through the red color region, a blue light emitted through the blue color region and a green light emitted through the green color region may be calibrated by the organic layer 344 of the mirror substrate.

In particular, the organic layer 344 does not cover an entire bottom surface of the mirror layer 330, and the organic layer 344 is selectively and discontinuously stacked under the portion of the mirror layer 330 such that a manufacturing cost decreases.

In some exemplary embodiments, although not illustrated in FIGS. 1 to 12, the mirror layer 330 included in the mirror substrate 300 of FIG. 1, the mirror layer 330 included in the mirror substrate 302 of FIG. 9, and the mirror layer 330 included in the mirror substrate 304 of FIG. 11 may be omitted.

The foregoing is illustrative of exemplary embodiments and is not to be construed as limiting thereof. Although a few exemplary embodiments have been described, those skilled in the art will readily appreciate that many modifications are possible in the exemplary embodiments without materially departing from the novel teachings and advantages of the invention. Accordingly, all such modifications are intended to be included within the scope of the invention as defined in the claims. Therefore, it is to be understood that the foregoing is illustrative of various exemplary embodiments and is not to be construed as limited to the specific exemplary embodiments disclosed, and that modifications to the disclosed exemplary embodiments, as well as other exemplary embodiments, are intended to be included within the scope of the appended claims.

What is claimed is:

1. A mirror display apparatus comprising:
a display unit disposed on a first substrate of a display substrate; and
a mirror substrate facing the display substrate and comprising:
a mirror pattern provided in plural on a second substrate facing the first substrate with respect to the display unit;
an organic layer facing the first substrate with respect to the display unit; and
a mirror layer extending continuously between the mirror patterns and the organic layer.

2. The mirror display apparatus of claim 1, wherein the organic layer includes Alq3 (8-hydroxyquinoline aluminum).

3. The mirror display apparatus of claim 1, wherein the organic layer facing the first substrate with respect to the display unit extends continuously between the mirror layer and the display unit.

4. The mirror display apparatus of claim 1, wherein the organic layer facing the first substrate with respect to the display unit extends discontinuously between the mirror layer and the display unit to be disposed between adjacent mirror patterns.

5. The mirror display apparatus of claim 1, wherein
the display unit includes an emitting region at which light is emitted and a non-emitting region at which light is not emitted,
the emitting region of the display unit is defined overlapping a stacked structure including the mirror layer and the organic layer of the mirror substrate, and
the non-emitting region of the display unit is defined overlapping a stacked structure including the mirror layer and each of the mirror patterns of the mirror substrate.

6. The mirror display apparatus of claim 5, wherein
the emitting region defines first and second color regions of the display unit, and
the organic layer defines a first portion thereof having a first thickness overlapping the first color region of the display unit and a second portion thereof having a second thickness overlapping the second color region of the display unit, and
the first and second thicknesses are substantially the same as each other.

7. The mirror display apparatus of claim 5, wherein
the emitting region defines first and second color regions of the display unit, and
the organic layer defines a first portion thereof having a first thickness overlapping the first color region of the display unit and a second portion thereof having a second thickness overlapping the second color region of the display unit, and
the first and second thicknesses are different from each other.

8. The mirror display apparatus of claim 5, wherein
the emitting region defines first to third color regions of the display unit,
the organic layer defines first to third portions thereof having a respective one of first to third thicknesses which overlaps a respective one of the first to third color regions, and
the first to third thicknesses are substantially the same as one another.

9. The mirror display apparatus of claim 8, wherein each of the first to third color regions is a respective one of a red color region, a green color region and a blue color region.

10. The mirror display apparatus of claim 5, wherein
the emitting region defines first to third color regions of the display unit,
the organic layer defines first to third portions thereof having a respective one of first to third thicknesses which overlaps a respective one of the first to third color regions, and
the first to third thicknesses are different from one another.

11. The mirror display apparatus of claim 10, wherein
each of the first to third color regions is a respective one of a red color region, a green color region and a blue color region, and
the first thickness is greater than the second and third thicknesses, and the third thickness is less than the first and second thicknesses.

12. The mirror display apparatus of claim 1, wherein the mirror pattern includes a metal.

13. The mirror display apparatus of claim 1, wherein the display unit includes an organic light emitting layer.

14. A mirror display apparatus comprising:
a display unit disposed on a first substrate of a display substrate, the display unit including an emitting region including first and second color regions; and
a mirror substrate facing the display substrate and comprising:
a mirror pattern provided in plural on a second substrate facing the first substrate with respect to the display unit; and
an organic layer facing the first substrate with respect to the display unit, the organic layer including first and second portions overlapping the first and second color regions, respectively,
wherein a first thickness of the first portion of the organic layer is different from a second thickness of the second portion of the organic layer.

15. The mirror display apparatus of claim 14, wherein the organic layer includes Alq3 (8-hydroxyquinoline aluminum).

16. The mirror display apparatus of claim 14, wherein
the display unit further includes a non-emitting region at which light is not emitted, and
the non-emitting region of the display unit is defined overlapping a structure including each of the mirror patterns of the mirror substrate.

17. The mirror display apparatus of claim 14, wherein
each of the first and second color regions is a respective one of a red color region and a green color region, and
the first thickness is greater than the second thickness.

18. The mirror display apparatus of claim 14, wherein
the emitting region further includes a third color region, and
the organic layer further includes a third portion overlapping the third color region, and
a third thickness of the third portion of the organic layer is different from the first and second thicknesses.

19. The mirror display apparatus of claim 18, wherein
each of the first to third color regions is a respective one of a red color region, a green color region and a blue color region, and
the first thickness is greater than the second and third thicknesses, and the third thickness is less than the first and second thicknesses.

20. The mirror display apparatus of claim 14, further comprising:
a mirror layer between the mirror patterns and the organic layer.
